(19) United States
(12) Patent Application Publication
(10) Pub. No.: US 2013/0147475 A1
(43) Pub. Date: Jun. 13, 2013

(54) MAGNETIC RESONANCE SYSTEM AND METHOD THEREOF

(71) Applicants: Xing YANG, Shanghai (CN); Teck Beng Desmond YEO, Clifton Park, NY (US); Xu CHU, Shanghai (CN); Thomas Kwok-Fah FOO, Clifton Park, NY (US)

(72) Inventors: Xing YANG, Shanghai (CN); Teck Beng Desmond YEO, Clifton Park, NY (US); Xu CHU, Shanghai (CN); Thomas Kwok-Fah FOO, Clifton Park, NY (US)

(21) Appl. No.: 13/314,559

(22) Filed: Dec. 8, 2011

(51) Int. Cl. G01R 33/48; G01R 33/385

(52) U.S. Cl. 324/309; 324/322

(57) ABSTRACT

A multi-channel coil assembly capable of being configured to operate in a first mode and a second mode is provided. The multi-channel coil assembly includes a plurality of coil elements and a plurality of mode switches. Each of the plurality of mode switches is switchably coupled to at least two of the coil elements. In the first mode, at least one of the mode switches is uncoupled to the coil elements forming a hyperthermia array. The hyperthermia array is configured to transmit first radio frequency signals in response to multiple first input signals supplied thereto. In the second mode, at least one of the mode switches is coupled to the coil elements forming a magnetic resonance (MR) array. The MR array is configured to transmit or receive second radio frequency signals in response to multiple second input signals supplied thereto.

### BACKGROUND

Embodiments of the disclosure relate generally to magnetic resonance systems, and more particularly relate to a magnetic resonance system integrated with hyperthermia and magnetic resonance imaging functions, and a method to switch between these functions.

Many clinical studies have shown the effectiveness of adjuvant hyperthermia when it is used in conjunction with radiotherapy and chemotherapy for cancer treatment. Increased tumor cell kill-rate is attained when the temperature in a tumor remains within 41° C. to 43° C. for a predefined period of time, while safety considerations require that the temperature of normal healthy tissue remains below some predetermined limit. In hyperthermia treatment, it is therefore necessary to control the temperature throughout the heated volume. Temperatures can be measured by invasive means, such as thermocouples, thermistors, or fiber-optic probes. However, only regions in close proximity to the probes can be monitored with these technologies, and thus, spatial sampling density of temperature is low. Furthermore, probe insertion may be painful and hazardous.

Magnetic resonance (MR) is a non-invasive and non-ionizing technique, which may produce anatomical images in any orientation. In addition, temperature measurements can be obtained by means of magnetic resonance imaging. However, conventional MR systems are not designed to accommodate hyperthermia systems. It is very challenging to combine hyperthermia and MR functions in a system by simply placing conventional RF hyperthermia apparatus inside a standard MR scanner. Significant changes are typically required for both systems to avoid crosstalk and degraded MR thermometry data, which may significantly affect the ability to track the thermal dose delivered.

It is desirable to provide a magnetic resonance system capable of combining hyperthermia and MR functions together, and a method for operating the magnetic resonance system with combined functions to address the above-mentioned problems.

### BRIEF DESCRIPTION

In accordance with one embodiment disclosed herein, a coil assembly configured to operate in a first mode and a second mode is provided. The coil assembly includes a plurality of coil elements and a plurality of mode switches. Each mode switch is switchably coupled to at least two of the coil elements. In the first mode, at least one of the mode switches is switched off to uncouple at least two of the coil elements. The uncoupled coil elements transmit radio frequency signals in response to multiple first input signals supplied for heating. In the second mode, at least one of the mode switches is switched on to couple at least two of the coil elements. The coupled coil elements transmit or receive radio frequency signals in response to multiple second input signals supplied thereto for imaging.

In accordance with another embodiment disclosed herein, a magnetic resonance (MR) system is provided. The MR system includes a main magnet, a gradient coil, and a coil assembly. The main magnet is used for generating a main magnetic field. The gradient coil is used for applying gradient waveforms to the main magnetic field along selected gradient axes. The coil assembly includes a plurality of coil elements and a plurality of mode switches. Each mode switch is switchably coupled to at least two of the coil elements. When the plurality of mode switches is switched on, at least two of the coil elements are configured per channel to commonly receive an input RF signal with phase and magnitude for each channel. In this mode, the input RF signals enable magnetic resonance imaging for the monitoring of temperature in a region of interest in the subject. When the plurality of mode switches is switched off, each of the coil elements is configured to independently receive an input RF signal with phases and magnitudes that enable the targeting of a region of interest for heating.

In accordance with yet another embodiment disclosed herein, a method is provided for operating a magnetic resonance (MR) system. The MR system includes a plurality of coil elements, and a plurality of mode switches switchably coupled to the plurality of coil elements. The method for operating an MR-RF hyperthermia system includes at least the following actions: switching off the plurality of mode switches for uncoupling the plurality of coil elements; transmitting multi-channel radio frequency signals to a region of interest via the uncoupled coil elements; switching on the plurality of mode switches to constitute a plurality of coil groups, each coil group having at least two coupled coil elements; and transmitting multi-channel radio frequency signals to the region of interest or receiving multi-channel radio frequency signals from the region of interest through the plurality of coil groups.

In accordance with yet another embodiment disclosed herein, a computer-readable medium comprising non-transitory instructions stored thereon is provided. The non-transitory instructions may be executed by a magnetic resonance system to perform the following actions: switching off the plurality of mode switches for uncoupling the plurality of coil elements; transmitting multi-channel radio frequency signals to a region of interest via the uncoupled coil elements; switching on the plurality of mode switches to constitute a plurality of coil groups, each coil group having at least two coupled coil elements; and transmitting multi-channel radio frequency signals to the region of interest or receiving multi-channel radio frequency signals from the region of interest through the plurality of coil groups.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic block diagram of an exemplary magnetic resonance system in accordance with one embodiment of the present disclosure.

FIG. 2 is a perspective view of an exemplary coil assembly for use in the MR system illustrated in FIG. 1 in accordance with one embodiment of the present disclosure.

FIG. 3 is a simplified schematic block diagram of the MR system operating in a hyperthermia mode in accordance with one embodiment of the present disclosure.

FIG. 4 is a simplified schematic block diagram of the MR system operating in a MR mode in accordance with one embodiment of the present disclosure.

FIG. 5 is a simplified schematic block diagram of the MR system operating in a MR mode in accordance with another embodiment of the present disclosure.

FIG. 6 is a flowchart illustrating various steps of a method for operating the MR system with combined functions in accordance with an exemplary embodiment of the present disclosure.

FIG. 7 illustrates EM simulation results of SAR distribution by operating the MR system in the hyperthermia mode in accordance with an exemplary embodiment of the present disclosure.

FIG. 8 illustrates EM simulation results of B1⁺ field distribution by operating the MR system in the MR mode in accordance with an exemplary embodiment of the present disclosure.

### DETAILED DESCRIPTION

One or more specific embodiments of the present disclosure will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Unless defined otherwise, technical and scientific terms used herein have the same meaning as is commonly understood by one of ordinary skill in the art to which this disclosure belongs. The terms “first”, “second”, and the like, as used herein do not denote any order, quantity, or importance, but rather are used to distinguish one element from another. Also, the terms “a” and “an” do not denote a limitation of quantity, but rather denote the presence of at least one of the referenced items. The use of “including”, “comprising”, or “having” and variations thereof herein are meant to encompass the items listed thereafter and equivalents thereof as well as additional items. The terms “connected” and “coupled” are not restricted to physical or mechanical connections or couplings, and can include electrical connections or couplings, whether direct or indirect.

As discussed in detail below, embodiments of the present disclosure generally relates to a magnetic resonance (MR) system integrated with hyperthermia functions. More specifically, the MR system is provided with a particularly designed coil assembly. The coil assembly may be switched to operate at least in a first mode and a second mode. The first mode may be a hyperthermia mode, in which the coil assembly may be configured to enable a first function of hyperthermia treatment of a region of interest by irradiating radio frequency energies to the region of interest. The second mode may be a MR mode, in which the same coil assembly may be configured to enable a second function of temperature monitoring of the region of interest by radio frequency signals transmitting and receiving. Compared to conventional combination of a hyperthermia system and a MR system to get a hybrid system, using a single coil assembly with different operating modes may more effectively enable a MR system to provide hyperthermia functions. Because the coil assembly is switched to perform the hyperthermia functions and the MR thermometry functions, at least the problem of crosstalk between the hyperthermia system and the MR system is minimized or eliminated by the present disclosure. Moreover, the new designed coil assembly in some embodiments enables substantially contemporaneous heating and parallel imaging. The signal to noise ratio (SNR) is typically increased by placing the coil assembly closer to the body and the acquisition speed of MR thermometry can be increased by parallel imaging.

For better understanding the present disclosure, the detail description will be first made to an overall MR system.

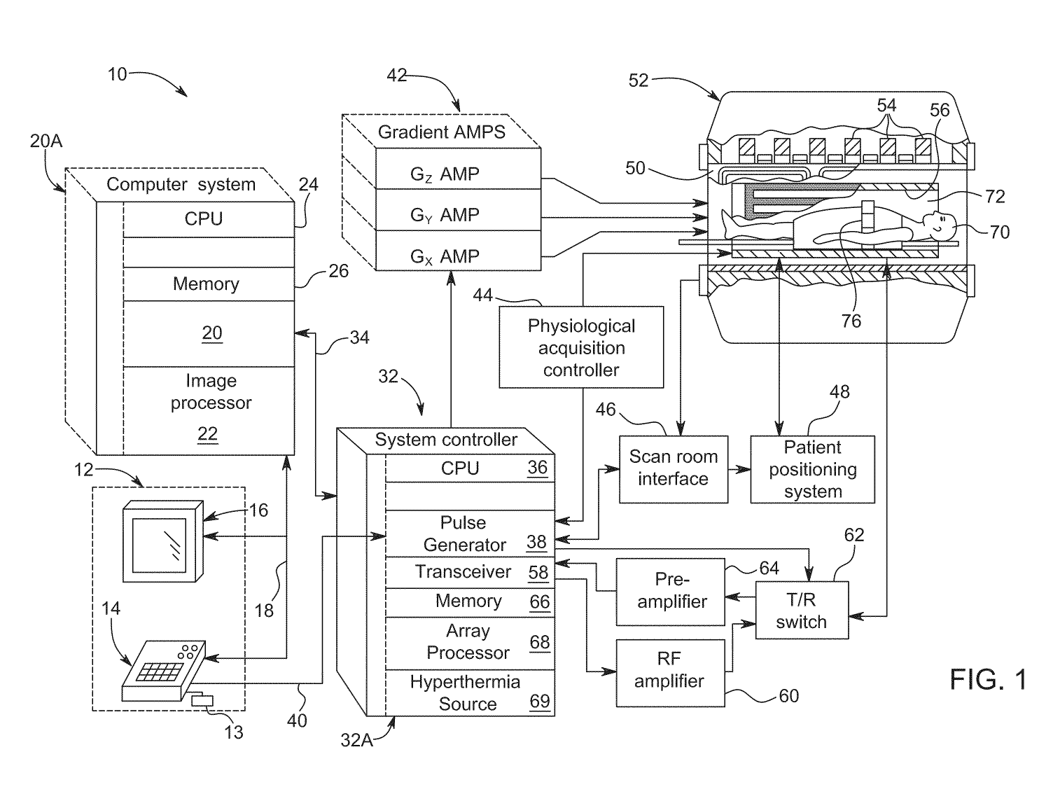

Turning now to the figures, FIG. 1 is a schematic block diagram of an exemplary magnetic resonance (MR) system in accordance with an embodiment. The operation of MR system 10 is controlled from an operator console 12 that includes an input device 13, a control panel 14, and a display 16. The operator console 12 communicates through a link 18 with a computer system 20 and provides an interface for an operator to prescribe MR scans, display resultant images, perform image processing on the images, and archive data and images. The input device 13 may include a mouse, joystick, keyboard, track ball, touch activated screen, light wand, voice control, or any similar or equivalent input device, and may be used for interactive geometry prescription.

The computer system 20 includes a number of modules that communicate with each other through electrical and/or data connections, for example, such as are provided by using a backplane 20a. Data connections may be wired links or wireless communication links or the like. The modules of the computer system 20 may include an image processor module 22, a CPU module 24, and a memory module 26. The memory module 26 may include a frame buffer for storing image data arrays. In an alternative embodiment, the image processor module 22 may be replaced by image processing functionality on the CPU module 24. The computer system 20 may be linked to archival media devices, permanent or back-up memory storage or a network. The computer system 20 may also communicate with a separate system control computer 32 through a link 34.

The system control computer 32 in one aspect includes a set of modules in communication with each other via electrical and/or data connections 32a. Data connections 32a may be wired links or wireless communication links or the like. In alternative embodiments, the modules of computer system 20 and system control computer 32 may be implemented on the same computer system or a plurality of computer systems. The modules of system control computer 32 may include a CPU module 36 and a pulse generator module 38 that connects to the operator console 12 through a communications link 40.

The pulse generator module 38 in one example is integrated into the scanner equipment (e.g., resonance assembly 52). It is through link 40 that the system control computer 32 receives commands from the operator to indicate the scan sequence that is to be performed. The pulse generator module 38 operates the system components that play out (i.e., perform) the desired pulse sequence by sending instructions, commands and/or requests describing the timing, strength and shape of the RF pulses and pulse sequences to be produced and the timing and length of the data acquisition window. The pulse generator module 38 connects to a gradient amplifier system 42 and produces data called gradient waveforms that control the timing and shape of the gradient pulses that are used during the scan. The pulse generator module 38 may also receive patient data from a physiological acquisition controller 44 that receives signals from a number of different sensors connected to the patient, such as ECG signals from electrodes attached to the patient. The pulse generator module 38 connects to a scan room interface circuit 46 that receives signals from various sensors associated with the condition of the patient and the magnet system. It is also through the scan room interface circuit 46 that a patient positioning system 48 receives commands to move the patient table to the desired position for the scan.

The gradient waveforms produced by the pulse generator module 38 are applied to the gradient amplifier system 42 that is comprised of Gx, Gy, and Gz amplifiers. Each gradient amplifier excites a corresponding physical gradient coil in a gradient coil assembly generally designated 50 to produce the magnetic field gradient pulses used for spatially encoding acquired signals. The gradient coil assembly 50 forms part of a resonance assembly 52 that includes a polarizing superconducting magnet with superconducting main coils 54. Resonance assembly 52 may include a whole-body RF coil 56, surface or parallel imaging coils 76 or both. The coils 56, 76 of the RF coil assembly may be configured for both transmitting and receiving or for transmit-only or receive-only. A patient or imaging subject 70 may be positioned within a cylindrical patient imaging volume 72 of the resonance assembly 52. A transceiver module 58 in the system control computer 32 produces pulses that are amplified by an RF amplifier 60 and coupled to the RF coils 56, 76 by a transmit/receive switch 62. The resulting signals emitted by the excited nuclei in the patient may be sensed by the same RF coil 56 and coupled through the transmit/receive switch 62 to a preamplifier 64. Alternatively, the signals emitted by the excited nuclei may be sensed by separate receive coils such as parallel coils or surface coils 76. The amplified MR signals are demodulated, filtered and digitized in the receiver section of the transceiver 58. The transmit/receive switch 62 is controlled by a signal from the pulse generator module 38 to electrically connect the RF amplifier 60 to the RF coil 56 during the transmit mode and to connect the preamplifier 64 to the RF coil 56 during the receive mode. The transmit/receive switch 62 can also enable a separate RF coil (for example, a parallel or surface coil 76) to be used in either the transmit mode or receive mode.

The MR signals sensed by the RF coil 56 are digitized by the transceiver module 58 and transferred to a memory module 66 in the system control computer 32. Typically, frames of data corresponding to MR signals are stored temporarily in the memory module 66 until they are subsequently transformed to create images. An array processor 68 uses a known transformation method, most commonly a Fourier transform, to create images from the MR signals. These images are communicated through the link 34 to the computer system 20 where it is stored in memory. In response to commands received from the operator console 12, this image data may be archived in long-term storage or it may be further processed by the image processor 22 and conveyed to the operator console 12 and presented on the display 16. The system control computer 32 further includes a hyperthermia source for generating hyperthermia RF signals.

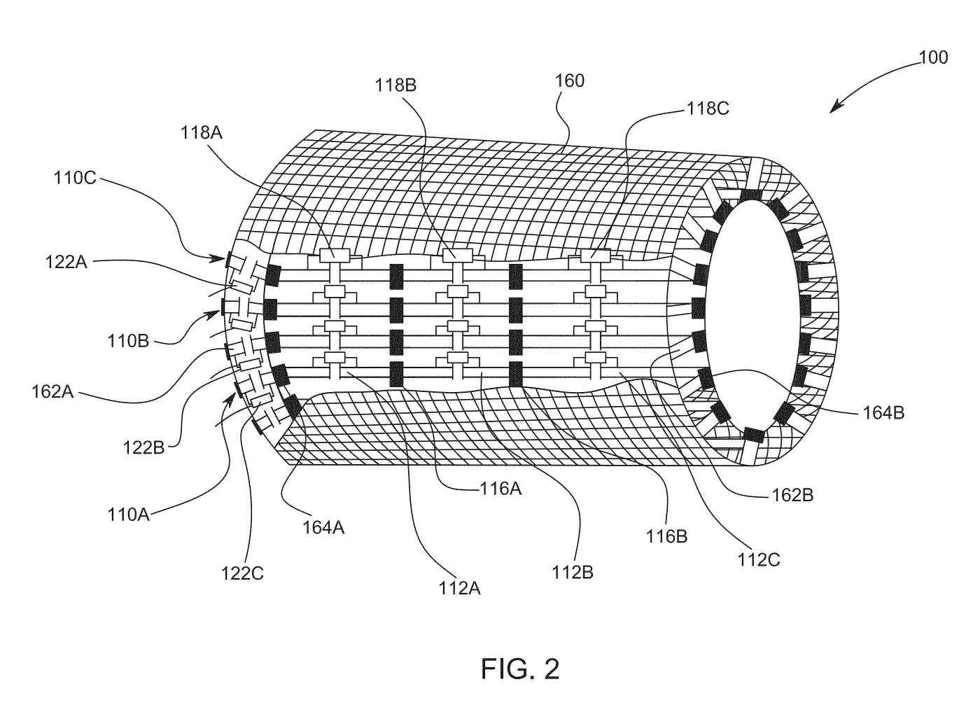

FIG. 2 illustrates an exemplary configuration of a hybrid mode coil assembly 100 for used in an MR system, such as that shown in FIG. 1. As used herein, the term “hybrid mode coil assembly” may refer to a coil assembly capable of being configured to operate in at least two modes. For example, the coil assembly 100 may be configured to operate in a first mode or hyperthermia mode of transmitting electromagnetic radiations to a region of interest for hyperthermia purpose. The coil assembly 100 may be configured to operate in a second mode or a MR mode. In the MR mode, the coil assembly 100 is configured for transmitting radio frequency signals to the region of interest, and for receiving radio frequency signals from the region of interest. By analyzing the received radio frequency signals, temperatures and/or temperature distribution of the region of interest can be determined The MR mode may be referred to as MR thermometry mode when the coil assembly 100 is operated to monitor temperatures and/or temperature distribution of the region of interest by radio frequency transmitting and receiving.

In one implementation, the coil assembly 100 may be implemented as a whole-body coil for used in the MR system 10. In other implementations, the coil assembly 100 may be implemented as a head coil, a torso coil, a neck-spine coil, a wrist coil, or a knee coil for used in the MR system 10.

Referring to FIG. 2, in one implementation, the coil assembly 100 may be implemented as a transverse-electromagnetic (TEM) RF coil for parallel transmit and/or parallel imaging. As used herein, “parallel transmit” may refer to multiple coil elements driven by individual drivers, and “parallel imaging” may refer to multiple coil elements that receive signals via multiple channels respectively. The coil assembly 100 may be arranged to have a plurality of coil groups 110a, 110b, and 110c. As shown in FIG. 2, in one implementation, the coil assembly 100 may include sixteen coil groups. In other implementations, fewer or more coil groups may be used. For example, in certain embodiments, eight groups, twelve groups, twenty-four groups, or thirty-two groups may be configured based on practical requirements. Furthermore, in operating coil assembly 100 having sixteen coil groups, a set of eight coil groups may be particularly enabled to transmit or receive multi-channel radio frequency signals and another set of eight coil groups may be disabled.

As further shown in FIG. 2, in one implementation, the plurality of coil groups 110a, 110b, and 110c is spaced uniformly or equally around the surface of a hollow cylinder (not shown). The cylinder may be a dielectric shell for surrounding a human body. The plurality of coil groups 110a, 110b, and 110c may be formed on the cylinder using adhesive or metal deposition processes. It is understood that, in alternative embodiments, the plurality of coil groups 110a, 110b, and 110c may be unequally spaced around the surface of the hollow cylinder. In other implementations, the plurality of coil groups 110a, 110b, and 110c may be arranged around the surface of any other structures, such as an elliptical cylinder, an eye-shaped cylinder, or an octagonal body.

In one implementation, each of the plurality of coil groups 110a, 110b, and 110c may include three coil elements 112a, 112b, and 112c. In other implementations, fewer or more coil elements may be used for each coil group. The three coil elements 112a, 112b, and 112c in each coil group are substantially linearly stacked end to end along the same direction. It is understood that the three coil elements 112a, 112b, and 112c may be viewed as extending along the direction of the E-field polarization axis with the coil assembly 100 operating in the hyperthermia mode. It is also understood that the three coil elements 112a, 112b, and 112c may be viewed as extending along the direction of the main magnetic field B₀ with the coil assembly 100 operating in the MR mode. In one implementation, the three coil elements 112a, 112b, and 112c may include dipole antennas. Although for purpose of description and not by way of limitation, dipole antennas are used throughout the description, the types of antenna may include patch, metal strips, metallic waveguide, dielectric waveguides, and resonant cavities. In one implementation, the dipole antennas 112a, 112b, and 112c may be made of metallic conductive strips, and each may include a first strip and a second strip.

Further referring to FIG. 2, within each of the plurality of coil groups 110a, 110b, and 110c, a plurality of mode switches 116a and 116b is switchably coupled to the dipole antennas 112a, 112b, and 112c. The plurality of mode switches 116a and 116b may be switched on or off in order to couple or decouple, respectively, the dipole antennas 112a, 112b, and 112c. The plurality of mode switches 116a and 116b is configured for switching the coil assembly 100 between at least two modes. The plurality of mode switches 116a and 116b may comprise mechanically activated switches or electrically activated switches. Each of the plurality of mode switches 116a and 116b may be individually controlled for selectively coupling or uncoupling any two neighboring dipole antennas. In one implementation, the plurality of mode switches 116a and 116b within each coil group 110a, 110b, and 110c may be all turned on, and the dipole antennas 112a, 112b, and 112c in each coil group 110a, 110b, and 110c are electrically coupled together. In this case, the coil assembly 100 may be operated in the MR mode. In another implementation, the plurality of mode switches 116a and 116b within each coil group 110a, 110b, and 110c may be all turned off, and the dipole antennas 112a, 112b, and 112c in each coil group 110a, 110b, and 110c are uncoupled from each other. In this case, the coil assembly 100 may be operated in the hyperthermia mode.

With continuing reference to FIG. 2, the coil assembly 100 may further include a shield 160. The shield 160 may be formed of a copper mesh or other conductive materials. The shield 160 may act as a current return path when the coil assembly 100 operates in the MR mode. Each of the plurality of coil groups 110a, 110b, and 110c is electrically coupled to the shield 160. More specifically, the dipole antenna 112a located at one side of the coil group is electrically coupled to one end of the shield 160 via a conductor 162a and a mode switch 164a. The dipole antenna 112c located at the other side of the coil group is electrically coupled to the other end of the shield 160 via a conductor 162b and a mode switch 164b. The two conductors 162a and 162b may project upwardly with respect to the dipole antennas 112a and 112c, such that the shield 160 may be spaced apart from the plurality of coil groups 110a, 110b, and 110c by a distance. When the coil assembly 100 is operating in the hyperthermia mode, the two mode switches 164a and 164b are turned off for uncoupling the dipole antennas 112a and 112c from the shield 160. When the coil assembly 100 is operating in the MR mode, the two mode switches 164a and 164b are turned on, and the shied 160 in combination with each coil group can form a closed resonance loop.

With continuing reference to FIG. 2, for each of the plurality of coil groups 110a, 110b, and 110c, the coil assembly 100 may further include a plurality of first control switches 118a, 118b, and 118c. Each of the plurality of first control switches 118a, 118b, and 118c is switchably coupled to corresponding dipole antennas 112a, 112b, and 112c. Each of the first control switches 118a, 118b, and 118c is capable of being individually turned on or off for allowing or preventing the hyperthermia input RF signals to pass through.

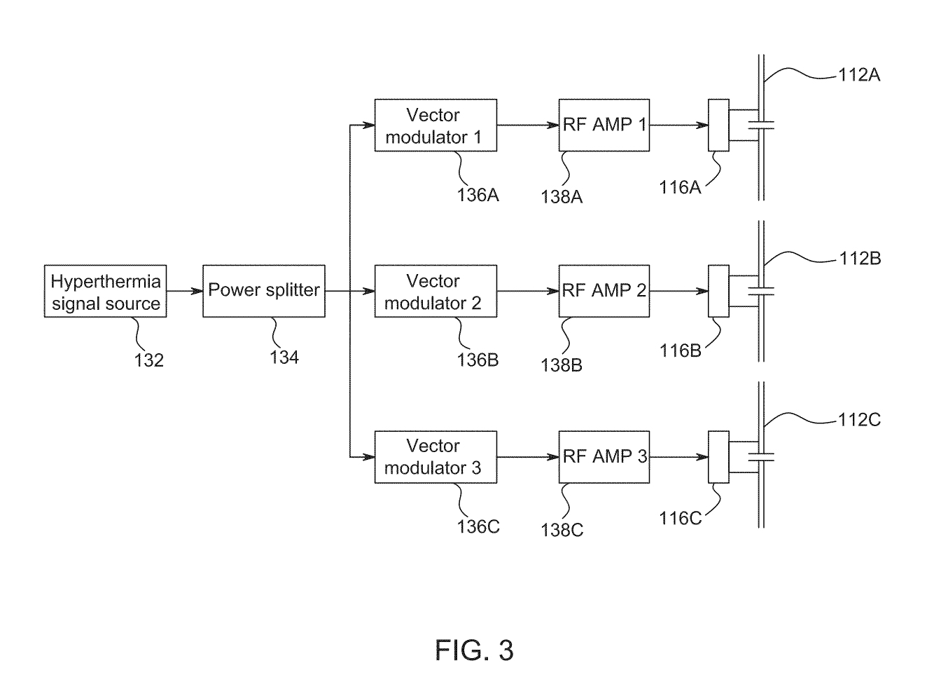

Referring to FIG. 3, each of the plurality of first control switches 118a, 118b, and 118c are coupled between the plurality of dipole antennas 112a, 112b, and 112c and a hyperthermia signal source 132. The hyperthermia signal source 132 is configured for supplying hyperthermia input RF signals to each of the dipole antennas 112a, 112b, and 112c via the plurality of first control switches 118a, 118b, and 118c. The hyperthermia signal source 132 may provide hyperthermia input RF signals in a frequency range of 40 to 1000 MHz. In some implementations for deep region heating, the frequency range is limited to 40 to 200 MHz.

With continuing reference to FIG. 3, a power splitter 134 may be introduced for splitting the hyperthermia signals generated from the hyperthermia signal source 132 into multiple channels. As shown in FIG. 3, the hyperthermia input RF signals split by the power splitter 134 are supplied to the three dipole antennas 112a, 112b, and 112c via three individual channels. In other implementations, more than one dipole antennas may be configured to commonly receive single channel hyperthermia input RF signals. For example, in certain embodiments, the dipole antennas 112a, 112b, and 112c may be commonly supplied with a hyperthermia input RF signal transmitted in a single channel.

With continuing reference to FIG. 3, a plurality of vector modulators 136a, 136b, and 136c may be further introduced for adjusting phase and amplitude of the hyperthermia input RF signals. In one implementation, each of the plurality of vector modulators 136a, 136b, and 136c may include a phase shifter and an attenuator for adjusting phase and magnitude of the hyperthermia signals respectively. By individually adjusting the phase and magnitude of the hyperthermia signals applied to each of the dipole antennas 112a, 112b, and 112c, the focused point or region and intensity of the radio frequency energy transmitted from the dipole antennas 112a, 112b, and 112c can be controlled. In one implementation, adjusting the phase and amplitude of the hyperthermia input RF signals applied to the plurality of dipole antennas 112a, 112b, and 112c enables 3D steering, and an optimal specific absorption rate (SAR) steering could be obtained.

With continuing reference to FIG. 3, a plurality of RF power amplifiers 138a, 138b, and 138c are electrically coupled to the plurality of vector modulators 136a, 136b, and 136c respectively. The plurality of RF power amplifiers 138a, 138b, and 138c is configured to provide the increase in signal power (gain) necessary for the dipole antennas 112a, 112b, and 112c to transmit radio frequency signals.

Referring back to FIG. 2, the coil assembly 100 may further include a plurality of second control switches 122a, 122b, and 122c. Each of the plurality of second control switches 122a, 122b, and 122c is switchably coupled to a corresponding coil group. Each of the plurality of second control switches 122a, 122b, and 122c is capable of being turned on or off for allowing or preventing the radio frequency MR signals to pass through. When one the plurality of second control switches 122a, 122b, and 122c is turned on, the corresponding coil group 100 may be configured to transmit radio frequency signals to a subject or receive radio frequency signals from a subject.

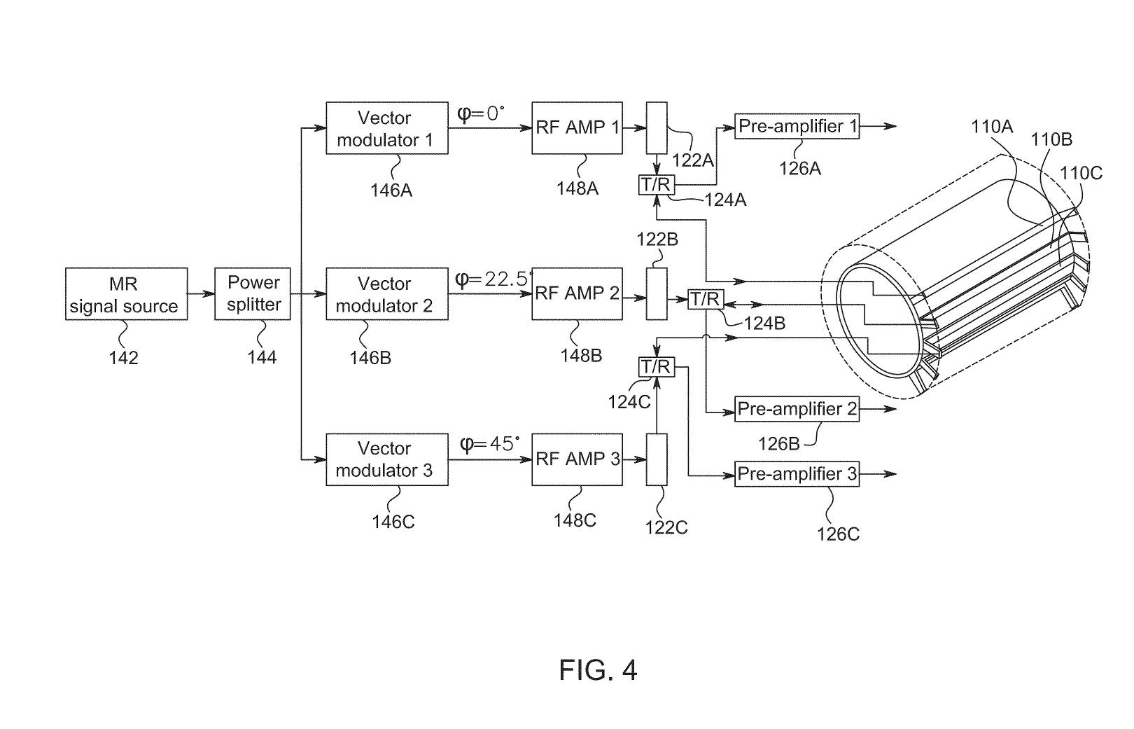

Referring to FIG. 4, in one embodiment, each of the plurality of coil groups 110a, 110b, and 110c may be in electrical communication with a MR signal source 142 via the plurality second control switch 122a, 122b, and 122c correspondingly. The MR signal source 142 may use the pulse generator module 38 shown in FIG. 1 for supplying radio frequency MR signals via the plurality of second control switches 122a, 122b, and 122c.

With continuing reference to FIG. 4, a power splitter 144 may be introduced for splitting the radio frequency MR signals generated from the MR signal source 142 into multiple channels. Moreover, a plurality of vector modulators 146a, 146b, and 146c, may be introduced corresponding to each of the multiple channels for performing phase and amplitude modulation of the radio frequency MR signals. In other implementations, instead of using the vector modulator, individual elements such as phase shifters and attenuators are used for adjusting phase and magnitude of the radio frequency MR signals. In one implementation, any two neighboring coil groups are supplied with radio frequency signals with equivalent phase difference. The phase difference may be determined according to the following equation:

Δφ=360°/N (1),

where N is a number of the coil group, Δφ is a phase difference between any adjacent two coil groups. When the coil assembly 100 has sixteen coil groups, it can be determined that the phase difference Δφ is 22.5°. In one implementation, multiple radio frequency MR signals individually supplied to the plurality of coil groups may be adjusted to have identical magnitude. In another implementation, the degrees of individual amplitude and phase adjustment of each radio frequency MR signal may be determined according to RF shimming design technique. Each of the radio frequency MR signals is therefore appropriately scaled and phase shifted to produce a substantially homogeneous B1 field.

With continuing reference to FIG. 4, a plurality of RF power amplifiers 148a, 148b, and 148c are electrically coupled to the plurality of vector modulators 146a, 146b, and 146c respectively. The plurality of amplifiers 148a, 148b, and 148c is configured to provide the increase in signal power (gain) necessary for the coil groups 110a, 110b, and 110c to transmit radio frequency signals.

Further referring to FIG. 4, a plurality of T/R switches 124a, 124b, and 124c are electrically coupled between the plurality of second control switches 122a, 122b, and 122c and the plurality of coil groups 110a, 110b, and 110c correspondingly. The plurality of T/R switches 124a, 124b, and 124c may be controlled by signals from the pulse generator module 38 (see FIG. 1) to electrically connect the plurality of amplifiers 148a, 148b, and 148c to the plurality of coil groups 110a, 110b, and 110c corresponding during the transmit mode and to connect a plurality of preamplifiers 126a, 126b, 126c to the coil groups 110a, 110b, and 110c during the receive mode.

As described with reference to FIG. 3 and FIG. 4, individual signal sources, i.e., the hyperthermia RF signal source 132 and the MR RF signal source 142 are separately employed to generate the hyperthermia radio frequency signals and the MR radio frequency signals separately. In other implementations, a single signal source may be used for generating radio frequency signals that is shared by both systems for performing heating and imaging at the same frequency. This will allow a common RF transmit chain to be shared by both functional modes, thus reducing equipment footprint, and cost to the clinician.

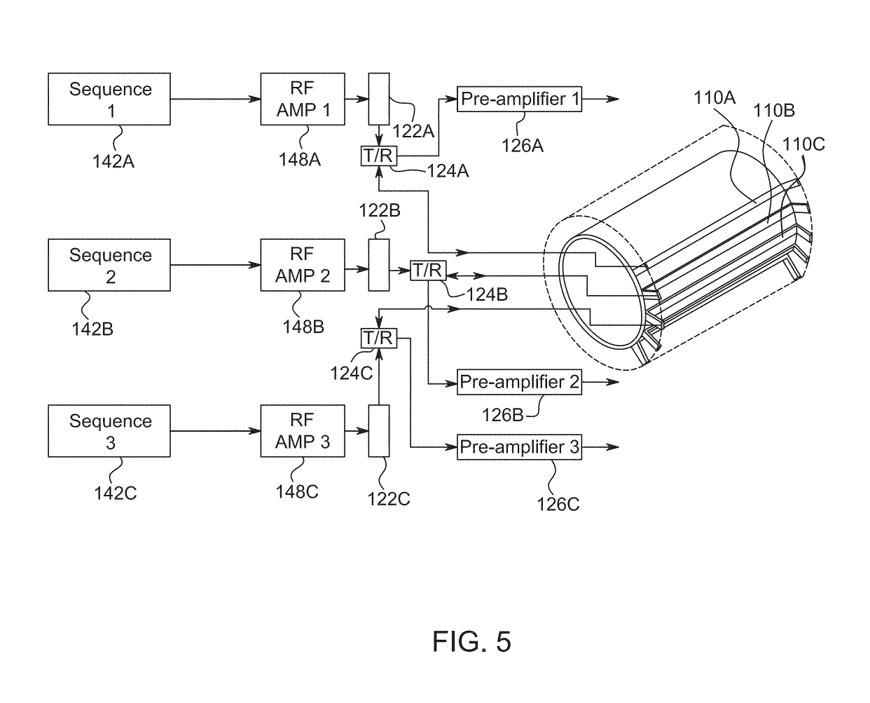

Referring to FIG. 5, in an alternative embodiment, instead of using a single MR signal source (described in FIG. 4) to generate radio frequency MR signals, multiple MR signal sources may be employed. As shown in FIG. 5, the plurality of coil groups 110a, 110b, and 110c may be in electrical communication with a plurality of MR signal sources 142a, 142b, and 142c via the plurality second control switches 122a, 122b, and 122c correspondingly. Each of the plurality of MR signal sources 142a, 142b, and 142c is configured to generate radio frequency pulse sequences that are specific to each of the plurality of coil groups 110a, 110b, and 110c. Since the plurality of coil groups 110a, 110b, and 110c are individually driven by the radio frequency pulse sequences, by designing an RF pulse sequence that is specific to each coil groups, aliasing sidelobes may be reduced to induce spatio-temporal variations in a composite B1 field.

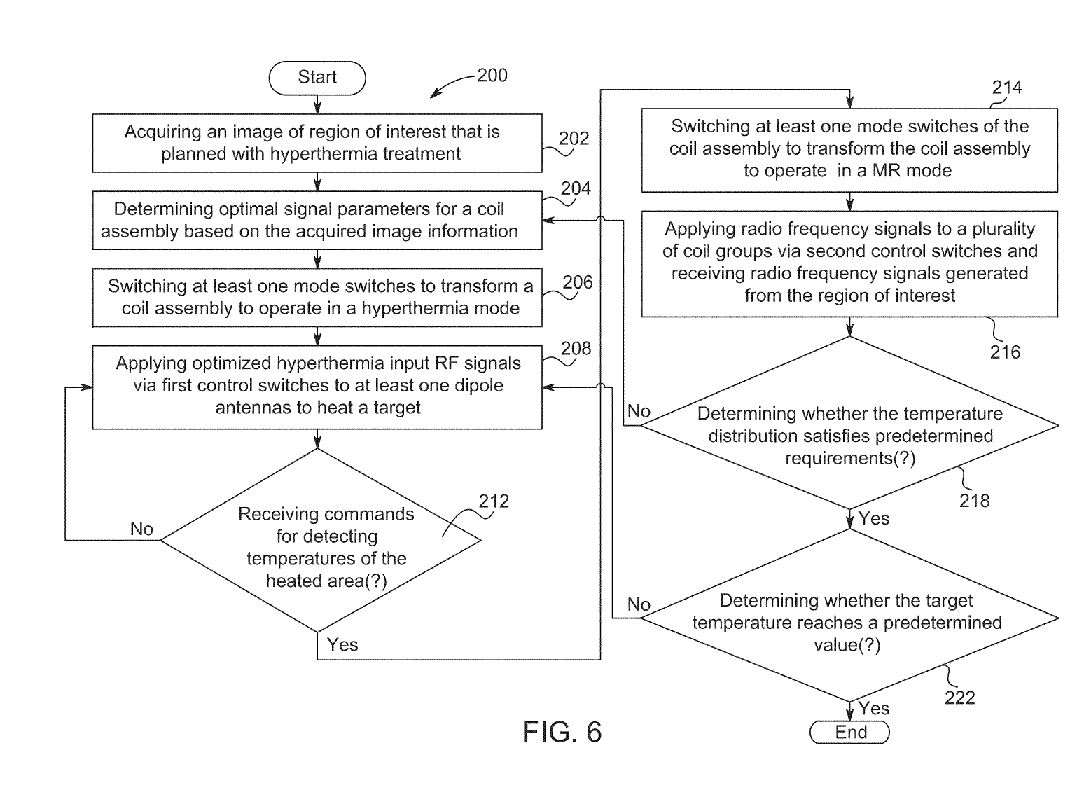

FIG. 6 illustrates a flowchart of a method 200 for operating a magnetic resonance system, such as the magnetic resonance system 100 shown in FIG. 1. The method 200 may be programmed with instructions stored in a computer-readable medium, which when executed by a processor, perform various steps of the method 200. The computer-readable medium may include volatile and nonvolatile, removable and non-removable media implemented in any method or technology. The computer-readable medium includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can accessed by an instruction execution system.

In one implementation, the method 200 may begin at block 202. At block 202, an image of a region of interest that is planned with hyperthermia treatment is acquired. In one implementation, the MR system 10 as shown in FIG. 1 may be used to acquire the image of the region of interest. More specifically, the coil assembly 100 may be switched for transmitting radio frequency signals to excite the nuclei in the region of interest. The coil assembly 100 may be further configured to receive radio frequency signals generated from the excited nuclei of the region of interest, such that an image of the region of interest may be acquired. In other implementations, other imaging systems including, but not limited to, computed tomography (CT) systems, may be used to acquire image of the region of interest.

At block 204, the method 200 may continue to determine optimized signal parameters for the coil assembly 100 based on the acquired image information. More specifically, the image acquired at block 202 may be segmented to identify different tissue types as well as tumors. EM numerical simulations are then performed to obtain each dipole antenna's electric fields (E-fields). Given these E-fields and the subject's electrical conductivity distribution, optimized signal parameters including antenna phases and amplitudes can be determined

At block 206, upon the optimized signal parameters are determined, at least one mode switch of the coil assembly 100 may be switched for transforming the coil assembly 100 to operate in a hyperthermia mode. In one implementation, the mode switches 116a, 116b, as shown in FIG. 2 may be switched off for disconnecting the plurality of dipole antennas 112a, 112b, and 112c of the coil assembly 100 from each other, and the mode switches 164a and 164b may be switched off for disconnecting the dipole antennas from the shield 160.

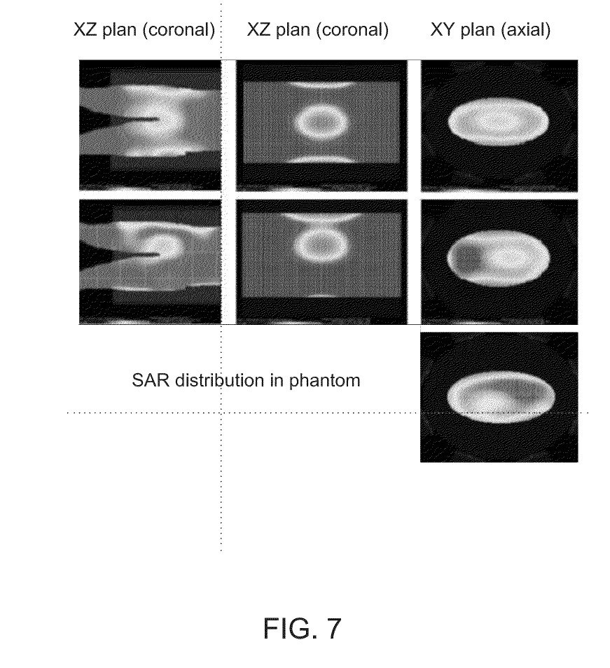

At block 208, the method 200 may continue to apply hyperthermia input RF signals to the coil assembly 100. Because the plurality of dipole antennas 112a, 112b, and 112c is disconnected from each other, each dipole antenna may be supplied with separate hyperthermia input RF signals. In one implementation, the plurality of first control switches 118a, 118b, and 118c in association with the plurality of dipole antennas 112a, 112b, and 112c may be turned on for supplying the hyperthermia input RF signals from the hyperthermia signal source 132 via multiple channels. The hyperthermia input RF signals may be split from the hyperthermia signal source 132 via the power splitter 134. Furthermore, the plurality of vector modulators 136a, 136b, and 136c may be used for adjusting the phase and amplitude of each of the hyperthermia input RF signals. FIG. 7 illustrates the simulation results of the SAR distribution in the phantom within the plurality of dipole antennas 112a, 112b, and 112c fed by adequate phases and amplitudes. As shown in FIG. 7, either in the XZ plane, or in the XY plane, a focused region of the RF energy can be controlled with phase and amplitude adjustments. Therefore, not only three-dimensional SAR/E-field steering is physically possible, but also a technical effect of steering the RF energy to diseased tissue regions while minimizing damage to healthy tissue can be achieved.

In other implementations, at block 208, when the coil assembly 100 operates in the hyperthermia mode, a bolus (not shown) containing high dielectric fluid or de-ionizing fluid may be positioned in the cylinder and around the human body. The bolus may be used to increase coupling of the RF energy to the human body and may be used to take away surface heat from the human body.

At block 212, the method 200 continues to determine whether a command is received for detecting a temperature of the target that is subject to a hyperthermia treatment. In one implementation, the MR system 10 may receive the command from the input device 13 or the control panel 14 shown in FIG. 1. If the command for detecting the temperature of the target is received, the method 200 proceeds to block 214. If the command for detecting the temperature of the target is not received, the method 200 goes back to block 208 for performing hyperthermia treatment.

At block 214, the method 200 continues to transform the coil assembly 100 to operate in a MR mode by switching the plurality of mode switches. As described herein with respect to FIG. 2, the coil assembly 100 may include a plurality of coil groups 110a, 110b, and 110c. In the MR transmit mode, the mode switches 116a and 116b within the coil group may be turned on to electrically couple the dipole antennas 112a, 112b, and 112c together. The mode switches 164a and 164b may be turned on to electrically couple the dipole antennas 112a, 112b, and 112c to the shield 160 to form a closed resonance loop.

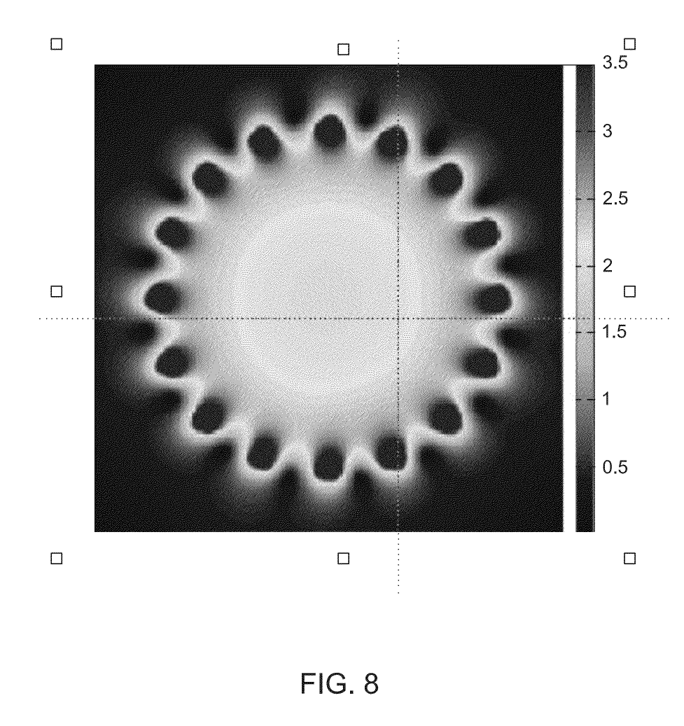

At block 216, the method 200 continues to apply radio frequency MR input signals to the plurality of coil groups 110a, 110b, and 110c, so as to transmit radio frequency signals to excite nuclei in the region of interest. In one implementation, each of the plurality of coil groups 110a, 110b, and 110c may be supplied with separate radio frequency MR signals. In one implementation, the plurality of second control switches 122a, 122b, and 122c in association with the plurality of coil groups 110a, 110b, and 110c may be turned on for supplying the radio frequency MR signals from the MR signal source 142 via multiple channels. The radio frequency MR signals may be split from the MR signal source 142 via the power splitter 144. Furthermore, the plurality of vector modulators 146a, 146b, and 146c may be used for adjusting the phase and amplitude of each of the radio frequency MR signals. FIG. 8 illustrates the simulation results of B1⁺ field distribution. The standard deviation of the B1⁺ map is less than 3%, and the calculated B1⁺ field is very homogeneous.

At block 216, the method 200 continues to receive radio frequency signals from the region of interest that is undergoing magnetic resonance imaging. As described above, the coil assembly 100 may include sixteen coil groups. When the coil assembly 100 receives radio frequency signals, in one implementation, all the sixteen coil groups are used for receiving the radio frequency signals. In other implementation, eight coil groups may be selected for receiving the radio frequency signals, while other eight coil groups are disabled. Then, a temperature of the subject can be detected by using the received radio frequency signals. In one implementation, a phase difference proton resonance frequency (PRF) shift thermometry method may be used for temperature mapping and distribution. The temperature change is estimated using the following relation:

$$Δ T = \frac{Δ ϕ}{γα {B}_{0} TE} , \qquad ( 2 )$$

where α is the thermal constant, γ is the gyromagnetic ratio, B₀ is the main magnetic field strength, TE is the echo time, and Δφ is the phase difference between a baseline image acquired before heating and a measurement image acquired during heating. In other implementations, the temperature may be detected based on the relationship of the relaxation time with the temperature.

At block 218, the method 200 continues to determine whether the detected temperature distribution satisfies predetermined requirements. For example, in hyperthermia treatment, normal tissues surrounding the region of interest should not be over-heated. If the temperature distribution doesn't satisfy predetermined requirements, the method 200 may move to block 204 for modifying the optimized signal parameters for the coil assembly 100. If the temperature distribution satisfies predetermined requirements, the method 200 proceeds to block 222.

At block 222, the method 200 continues to determine whether the detected temperature reaches predetermined value. For example, in hyperthermia treatment, a region may be heated to above a predetermined value for several minutes. For example, the predetermined value is a value in the range of about 41° C. to about 43° C. In one implementation, the MR system 10 may determine whether a temperature of the target exceed a predetermined value. If the region of interest is not sufficiently heated, the method 200 moves to block 208 for continuing heating the region of interest. If the region of interest is sufficiently heated, the method 200 may end.

The operations described in the method 200 of FIG. 6 do not necessarily have to be performed in the order set forth in FIG. 6, but instead may be performed in any suitable order. Additionally, in certain embodiments of the present disclosure, more or less than all of the elements or operations set forth in FIG. 6 may be performed.

It is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

Furthermore, a person skilled in the art will recognize the interchangeability of various features from different embodiments. The various features described, as well as other known equivalents for each feature, can be mixed and matched by one of ordinary skill in this art to construct additional systems and techniques in accordance with principles of this disclosure.

1. A multi-channel coil assembly configured to operate in a first mode and a second mode, the multi-channel coil assembly comprising:
a plurality of coil elements; and
a plurality of mode switches, each of the mode switches being switchably coupled to at least two of the plurality of coil elements;
wherein in the first mode, at least one of the mode switches is uncoupled to the coil elements forming a hyperthermia array, the hyperthermia array configured to transmit first radio frequency signals in response to multiple first input signals supplied thereto; and
wherein in the second mode, at least one of the mode switches is coupled to the coil elements forming a magnetic resonance (MR) array, the MR array configured to transmit or receive second radio frequency signals in response to multiple second input signals supplied thereto.

2. The multi-channel coil assembly of claim 1, wherein the multiple first input signals are supplied to the uncoupled coil elements for radio frequency hyperthermia treatment.

3. The multi-channel coil assembly of claim 2, further comprising a first signal source and a plurality of first control switches, wherein each of the plurality of first control switches is switchably coupled to the first signal source and a corresponding one of the plurality of coil elements; when the multi-channel coil assembly is operated in the first mode, at least one of the first control switches is switched on, the first signal source is communicatively coupled to the coil elements; when the multi-channel coil assembly is operated in the second mode, the plurality of first control switches is switched off, the first signal source is uncoupled to the coil elements.

4. The multi-channel coil assembly of claim 1, wherein the multiple second input signals are supplied to the coupled coil elements for temperature monitoring of a region of interest by magnetic resonance imaging.

5. The multi-channel coil assembly of claim 4, further comprising a second signal source and a plurality of second control switches, wherein each of the plurality of second control switches is switchably coupled to the second signal source and a corresponding one of the plurality of coil elements, when the multi-channel coil assembly is operated in the first mode, the plurality of second control switches is switched off, the second signal source is uncoupled to the plurality of coil elements; when the multi-channel coil assembly is operated in the second mode, at least one of the second control switches is switched on, the second signal source is communicatively coupled to a corresponding one of the coil elements.

6. The multi-channel coil assembly of claim 1, wherein the plurality of coil elements comprises dipole antennas.

7. The multi-channel coil assembly of claim 1, wherein when the plurality of mode switches is switched on, the plurality of coil elements constitutes a transverse electro-magnetic (TEM) coil assembly for parallel imaging.

8. The multi-channel coil assembly of claim 7, further comprising a shield connected as a common current return path for the multiple input signals applied to the plurality of coil elements.

9. A magnetic resonance system, comprising:
a main magnet for generating a main magnetic field;
a gradient coil for applying gradient waveforms to the main magnetic field along selected gradient axes; and
a multi-channel coil assembly comprising:
a plurality of coil elements; and
a plurality of mode switches, the plurality of mode switches being switchably coupled to a first set of at least two of the plurality of coil elements and a second set of at least two of the plurality of coil elements;
wherein when the plurality of mode switches is switched off, each of the plurality of coil elements is supplied with a first input signal with phase and magnitude and to independently transmit a first radio frequency signal to heat the region of interest; and
wherein when the plurality of mode switches is switched on, the first set of at least two of the plurality of coil elements are configured to commonly receive a second input signal with phase and magnitude in a first channel, the second set of at least two of the plurality of coil elements are configured to commonly receive a second input signal with phase and magnitude in a second channel, the first and second set of the plurality of coil elements transmit or receive second radio frequency signals to monitor a temperature of a region of interest by magnetic resonance imaging.

10. The magnetic resonance system of claim 9, wherein the first input signal supplied to the second set of at least two of plurality of coil elements in the second channel is subject to a phase shift with respect to the first input signal supplied to the first set of at least two of plurality of coil elements in the first channel.

11. The magnetic resonance system of claim 9, wherein when the plurality of mode switches are switched on, the coil assembly constitutes a transverse electro-magnetic coil having multiple coil groups, the multiple coil groups are independently supplied with second input signals through multiple channels, phase and amplitude of the second input signals transmitted through the multiple channels are adjusted according to radio frequency shimming technique.

12. The magnetic resonance system of claim 9, further comprising a first signal source and a plurality of first control switches, wherein the plurality of first control switches is switchably coupled to the first signal source, each of the plurality of first control switches is coupled to a corresponding one of the plurality of coil elements, the plurality of first control switches is configured to be switched on or off for enabling or disabling supplying the first input signals.

13. The magnetic resonance system of claim 9, further comprising a second signal source and a plurality of second switch elements, wherein the plurality of second switches is switchably coupled to the second signal source, each of the plurality of second switches is coupled to a corresponding one of the plurality of coil elements, the plurality of second switches is configured to be switched on or off for enabling or disabling supplying the second input signals.

14. A method for operating a magnetic resonance (MR) system, the MR system comprising a plurality of coil elements and a plurality of mode switches switchably coupled to the plurality of coil elements, the method comprising:
switching off the plurality of mode switches for uncoupling the plurality of coil elements;
transmitting multi-channel radio frequency signals to a region of interest via the uncoupled coil elements;
switching on the plurality of mode switches to constitute a plurality of coil groups, each coil group having at least two coupled coil elements; and
transmitting multi-channel radio frequency signals to the region of interest or receiving multi-channel radio frequency signals from the region of interest through the plurality of coil groups.

15. The method of claim 14, wherein the MR system comprises a plurality of first control switches, the method further comprising:
switching on the plurality of first control switches during transmitting multiple-channel radio frequency signals to the region of interest via the plurality of coil groups; and
switching off the plurality of first control switches during transmitting multiple-channel radio frequency signals to the region of interest via the uncoupled coil elements.

16. The method of claim 14, wherein the MR system comprises a plurality of second control switches, the method further comprising:
switching off the plurality of second control switches during transmitting multiple-channel radio frequency signals to the region of interest via the plurality of coil groups; and
switching on the plurality of second control switches during transmitting multiple-channel radio frequency signals to the region of interest via the uncoupled coil elements.

17. The method of claim 14, further comprising:
acquiring an image of the region of interest; and
determining optimal signal parameters of the plurality of coil elements based on the acquired image information.

18. The method of claim 17, further comprising:
detecting a temperature distribution of the region of interest by magnetic resonance imaging;
determining whether the detected temperature distribution satisfies a predetermined requirement; and
adjusting the optimal signal parameters upon determination that the detected temperature distribution does not satisfy the predetermined requirement.

19. The method of claim 17, further comprising:
detecting a temperature of the region of interest by magnetic resonance imaging;
determining whether the detected temperature reaches a predetermined value; and
transmitting the multi-channel radio frequency signals to the region of interest via the uncoupled coil elements upon determination that the detected temperature does not reach the predetermined value.

20. A non-transitory computer-readable medium comprising instructions stored thereon, which when executed by a processor of a magnetic resonance system perform the method comprising:
switching on a plurality of mode switches to form a plurality of coil groups, each coil group having at least two coupled coil elements;
transmitting multi-channel radio frequency signals to a region of interest or receiving multi-channel radio frequency signals from the region of interest through the plurality of coil groups;
switching off the plurality of mode switches for uncoupling the plurality of coil elements; and
transmitting multi-channel radio frequency signals to the region of interest via the uncoupled coil elements.
